(19) United States
(12) Patent Application Publication
(10) Pub. No.: US 2026/0191014 A1
(43) Pub. Date: Jul. 2, 2026

(54) ELECTROMAGNETIC INTERFERENCE FILTER

(71) Applicant: Texas Instruments Incorporated, Dallas, TX (US)

(72) Inventors: SUDHEER PRASAD, Bangalore (IN); SREERAM NASUM S, Bangalore (IN)

(21) Appl. No.: 19/004,775

(22) Filed: Dec. 30, 2024

(51) Int. Cl. H01L 23/66; H01L 23/522; H10D 1/47; H10D 89/60

(52) U.S. Cl. CPC H10W 44/20; H10D 1/47; H10D 89/911; H10W 20/498; H10W 44/209

(57) ABSTRACT

An IC, with: a first semiconductor diode, including a first portion of a first layer having a first conductivity type, a first portion of a second layer having a second conductivity type, and a first metal portion coupled to the first portion of the first layer, the first conductivity type opposite the second conductivity type and a first interface region aligned with the first metal portion and existing along an interface between the first and second layers; a second semiconductor diode, including a second portion of the first layer, a second portion of the second layer, a second metal portion coupled to the second portion of the first layer, and a second interface region aligned with the second metal portion and existing along the interface between the first and second layers; and a resistive region within the first layer and between the first interface region and the second interface region.

### CROSS-REFERENCE TO RELATED APPLICATION

Not applicable.

### BACKGROUND

Some examples described in this document relate to integrated circuits (ICs) and, more particularly to an IC with an electromagnetic interference (EMI) filter.

ICs pervade all manners of electronic devices. Some IC applications include or provide an EMI filter. One type of EMI filter includes two capacitances, one connected to each of opposing terminals of a metal thin-film resistor. EMI filters with a metal resistor have various uses and applications. However, there may be a need to provide an improved IC configuration with an EMI filter.

### SUMMARY

In an example, an IC, including: a first semiconductor diode, including a first portion of a first layer having a first conductivity type, a first portion of a second layer having a second conductivity type, and a first metal portion coupled to the first portion of the first layer, the first conductivity type opposite the second conductivity type and a first interface region aligned with the first metal portion and existing along an interface between the first and second layers; a second semiconductor diode, including a second portion of the first layer, a second portion of the second layer, a second metal portion coupled to the second portion of the first layer, and a second interface region aligned with the second metal portion and existing along the interface between the first and second layers; and a resistive region within the first layer and between the first interface region and the second interface region.

In another example, an IC, comprising a first semiconductor diode, including a first portion of a first layer having a first conductivity type, a first portion of a second layer having a second conductivity type, and a first metal portion coupled to the first portion of the first layer, the first conductivity type opposite the second conductivity type and a first depletion region having a first inherent capacitance aligned with the first metal portion and existing along an interface between the first and second layers; a second semiconductor diode, including a second portion of the first layer, a second portion of the second layer, a second metal portion coupled to the second portion of the first layer, and a second depletion region having a second inherent capacitance aligned with the second metal portion and existing along the interface between the first and second layers; and a resistive region in the first layer and between the first and second depletion regions.

In another example,
There is a method of forming an IC. The method comprises: forming a first layer with a first set of regions of a first conductivity type; forming a second layer with a second set of regions of a second conductivity type, wherein the second conductivity type is opposite to the first conductivity type and a first semiconductor diode is formed between a first region in the first set of regions and a first region in the second set of regions and a second semiconductor diode is formed between a second region in the first set of regions and a second region in the second set of regions; and forming a first electrical contact in contact with a cathode of the first semiconductor diode and a second electrical contact in contact with a cathode of the second semiconductor diode, and such that a resistive region is defined within the first layer between the first electrical contact and the second electrical contact.

Other aspects are also described and claimed.

### BRIEF DESCRIPTION OF THE DRAWINGS

FIGS. 1A and 1B illustrate a plan and cross-sectional view of an IC, respectively, including an EMI filter formed in connection with an IC semiconductor wafer.

FIG. 1C illustrates an electrical schematic equivalent to the EMI filter of FIGS. 1A and 1B.

FIGS. 2 through 5 illustrate processing steps leading to the formation of the FIGS. 1A and 1B IC.

FIGS. 6A and 6B illustrate a plan and cross-sectional view of an IC, respectively, including a first alternative EMI filter formed in connection with an IC semiconductor wafer.

FIG. 7 illustrates a plan view of an IC, including a second alternative EMI filter formed in connection with an IC semiconductor wafer.

FIG. 8 is a flow diagram of an example method summarizing various of the steps for manufacturing an IC with an EMI filter.

### DETAILED DESCRIPTION

A thin-film resistor may be formed from tantalum aluminide (TaAl). The TaAl resistor may be a layer in a semiconductor IC device, which may require a particular mask and corresponding processing to form the metal layer. Such an approach may exist as an option in some processes, but becomes infeasible if the process is not readily available or may otherwise present inefficiencies. This document provides examples that may improve on certain of the above concepts, as detailed below.

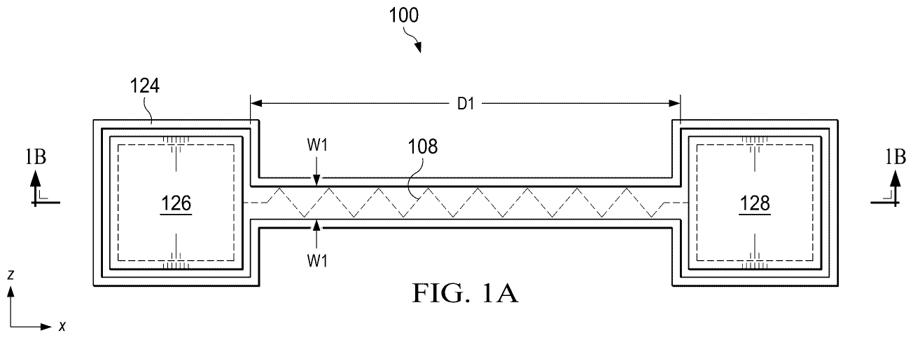

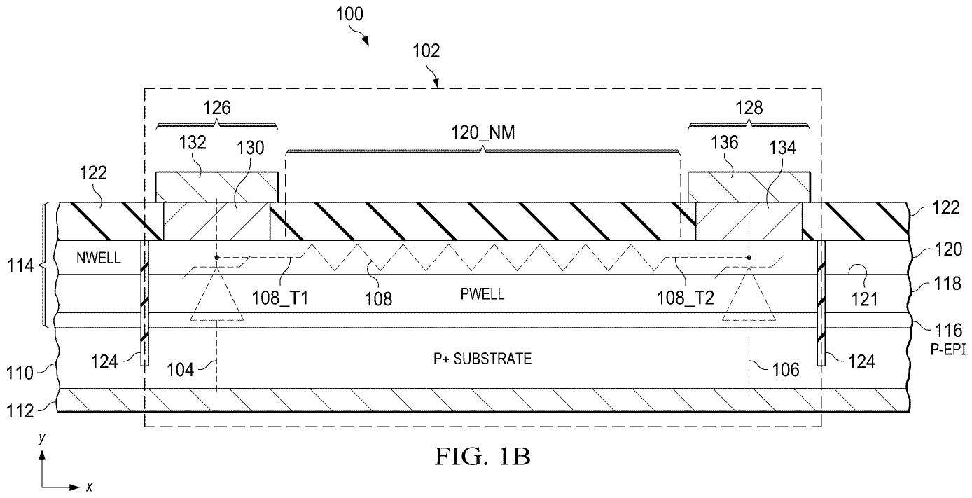

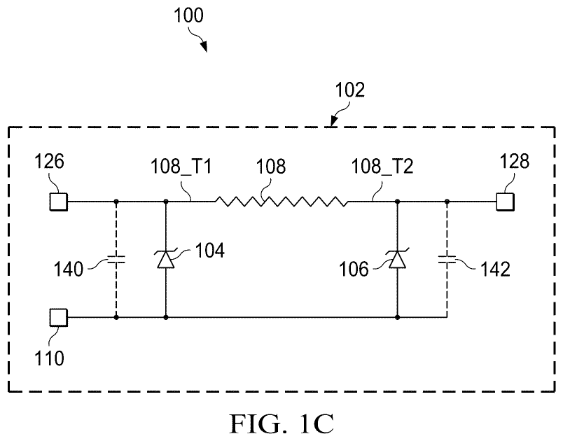

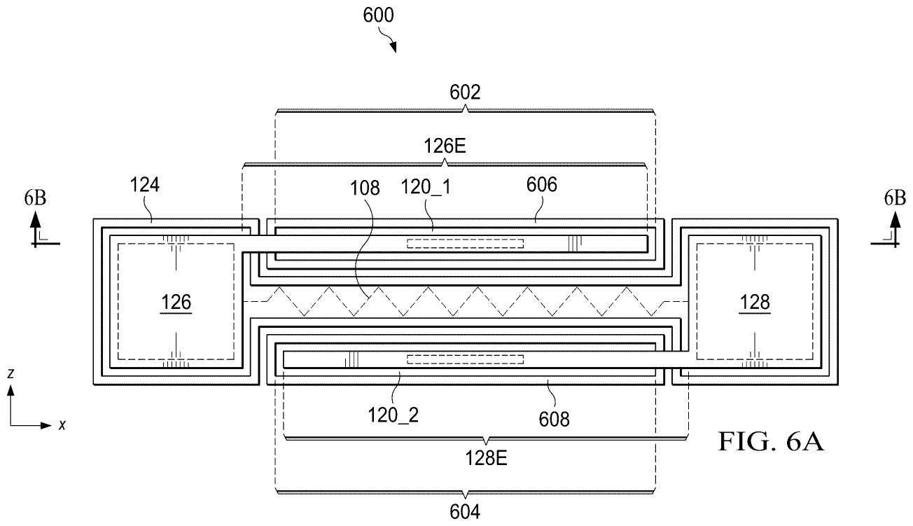

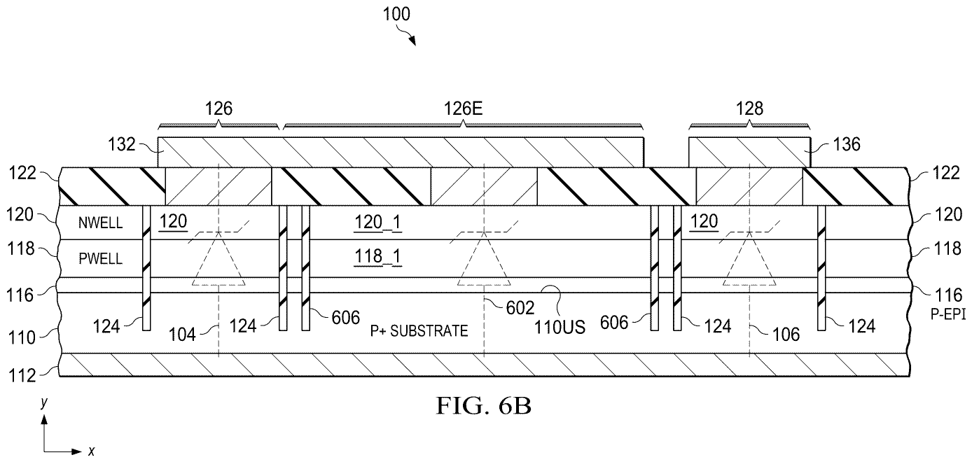

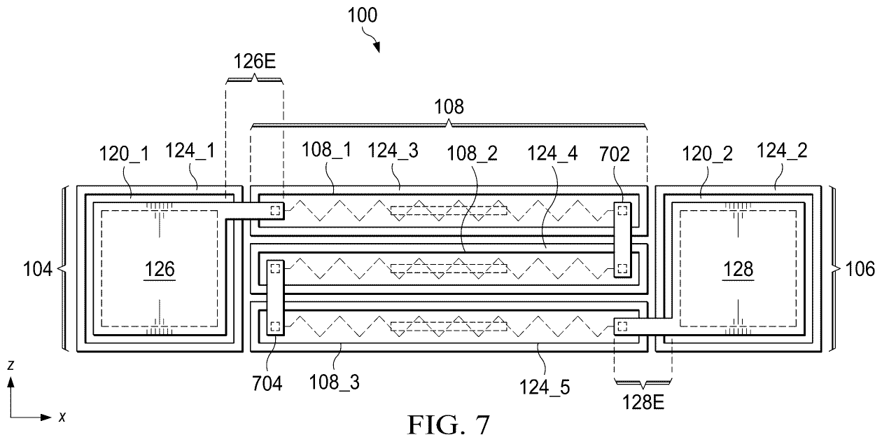

FIGS. 1A and 1B illustrate a plan and cross-sectional view of an IC 100, respectively, including an EMI filter 102. The EMI filter 102 includes various structures, as will be described. In FIG. 1B and various later figures, cross-sectional views are shown in an x/y (horizontal-vertical) plane but also have features in the z-dimension extending in a direction in and out of the illustrated x/y image plane, as shown in the FIG. 1A (and FIGS. 6A and 7) plan view. Also for sake of simplification, FIG. 1B is a partial view of FIG. 1A, in the sense that a layer 122, described below and shown in FIG. 1B, is not shown in FIG. 1A. Further, the IC 100 may be a discrete device providing generally or solely the EMI filter 102, without including other active devices (e.g., transistors) in the same IC device.

Electrically and as shown fully in FIG. 1B, the EMI filter 102 structures include a first vertical diode 104 and a second vertical diode 106. Each diode 104, 106 is shown as a phantom (dashed outline) schematic element corresponding to various layer structures and characteristics that provide the diode structure and functionality. In an example, each of the first vertical diode 104 and second vertical diode 106 may be a Zener diode, as indicated by the schematic representation. The two diodes may serve two different modes of operation. A first operation mode is a high-current operation of either diode under an electrostatic discharge (ESD) condition. In the ESD condition, the diode conducts and clamps voltage through reverse breakdown of the diode PN junction at a specified voltage (e.g., 12 volts), so as to protect any external circuit connected to the EMI filter 102. A second operation mode is a small signal (very lower current) operation. In this second mode, there is only a normal signal (i.e., non-ESD) present. Further in this second mode, the PN junction of each diode provides a depletion region that behaves similarly to a parallel-plate capacitor, oriented generally in the y-dimension and further described below, to serve in the EMI filter 102 to filter output small radio frequency (RF) noise present and provide a cleaner signal to the output.

Also electrically and shown in FIG. 1B, the EMI filter 102 includes a resistive region 108, also shown by phantom schematic. The resistive region 108 has a first terminal 108_T1 connected to the cathode of the first vertical diode 104 and a second terminal 108_T2 connected to the cathode of the second vertical diode 106. The resistive region 108 is formed structurally as described below, and may include dimensions D1 and W1 as detailed later.

Structurally and as formed by example processes described later, the EMI filter 102 is formed using various semiconductor fabrication layers and processes. Generally, the EMI filter 102 is formed using a semiconductor substrate 110, for example as may be obtained as a semiconductor wafer with a particular dopant concentration level, which in the illustrated example is a relatively high dose of p-type (P+) material. Below (in the relative sense of the y-dimension) the semiconductor substrate 110 is a backside metal layer 112. Above the semiconductor substrate 110 is a frontside layer stack 114, which in order upward from the semiconductor substrate 110 includes a p-type epitaxial (p-epi) layer 116, a p-type well (Pwell) layer 118, an n-type well (Nwell) layer 120, and an interlevel oxide (ILO) layer 122. The EMI filter 102 may be isolated around a portion, or all, of its perimeter, for example using a deep trench isolation region 124 which, as visible in the FIG. 1A perspective, surrounds the diodes 104 and 106 in the x/z plane. The EMI filter 102 also includes a first electrical terminal 126 and a second electrical terminal 128. The first electrical terminal 126, for example, includies a first electrical contact 130 touching and electrically coupled to a first electrical contact pad 132. The second electrical terminal 128, for example, includes a second electrical contact 134 touching and electrically coupled to second electrical pad 136.

Each of the first and second electrical contact pads 132 and 136 is formed atop the ILO layer 122. Each of the first and second electrical contacts 130 and 134 is formed through the ILO layer 122, and to contact the Nwell layer 120. Note that a contact and pad combination (i.e., either the contact 130 and the contact pad 132, or the contact 134 and the contact pad 136) may be formed from a same metal layer, or the contacts 130 and 134 may be first formed, after which the contact pads 132 and 136 are formed. The lateral outward distance, in the x-dimension between each of the first and second electrical contacts 130 and 132 to the vertical edge of the neighboring deep trench isolation region 124 may be, for example approximately 1 to 2 μm (and the width of each trench isolation region 124, in the x-dimension, also may be 2 μm or so).

FIG. 1C illustrates an electrical schematic equivalent to the EMI filter of FIGS. 1A and 1B, including the diodes 104 and 106 and the resistive region 108 connected between the cathodes of those diodes. Schematically to the left, a differential input is provided between the first electrical terminal 126 and the substrate 110 (shown also as an electrical terminal). Again, the first diode 104 anode is connected to the substrate 110 and the first vertical diode 104 cathode is connected to the first electrical terminal 126. FIG. 1C also illustrates a first capacitor 140 having a first terminal connected to the first vertical diode 104 anode (and to the substrate 110) and a second terminal connected to the first vertical diode 104 cathode (and to the first electrical terminal 126). The first capacitor 104 is shown in phantom, so as to depict that the capacitor is not a discrete electrical component per se, but is representative of the inherent capacitance provided at the PN interface (junction) of the first vertical diode 104.

The second vertical diode 106 is similarly shown to the schematic right, providing a differential output between the second electrical terminal 128 and the substrate 110. FIG. 1C also illustrates a second capacitor 142 having a first terminal connected to the second vertical diode 106 anode (and to the substrate 110) and a second terminal connected to the second vertical diode 106 cathode (and to the second electrical terminal 1268. The second capacitor 106 is also shown in phantom, again to depict that the capacitor is not a discrete electrical component per se, but is representative of the inherent capacitance provided at the PN interface (junction) of the second vertical diode 106. Accordingly, each of the first and second diodes 104 and 106 provides a reverse breakdown failsafe purpose as either may turn on, conduct high current (e.g., tens of Amperes), and clamp voltage so as to protect an external circuit connected to it. Further, the combination of the capacitive aspect of each of the diodes 104 and 106, and the resistive region 108 between the cathodes thereof, provides a capacitive-resistive-capacitive structure, thereby providing an overall electrical response of the EMI filter 102. Moreover, either or both the respective capacitance and resistance of the structure, so as to tune the bandwidth of the EMI filter 102.

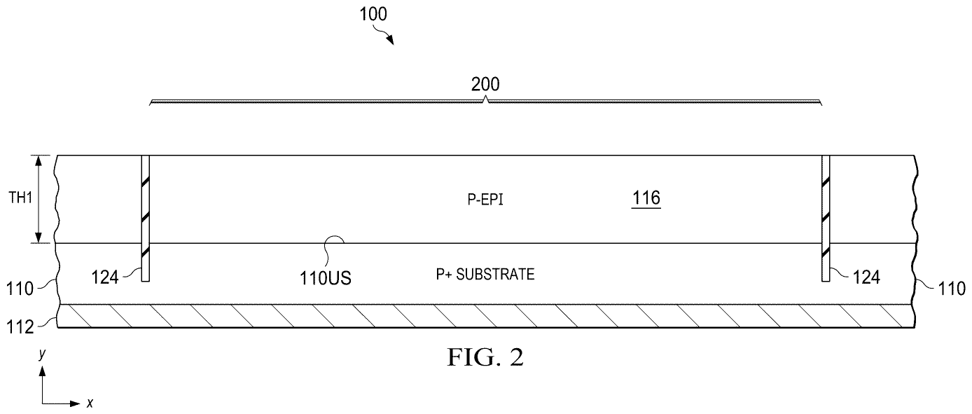

FIG. 2 illustrates a cross-sectional view of the IC 100 at an earlier processing step than as depicted in FIGS. 1A and 1B. In FIG. 2, the substrate 110 is obtained, which is shown to include a backside metal layer 112. However, since FIG. 2 is a relatively early stage, the actual backside metal layer 112 is contextual, as in fact it may be added at a later stage, for example after other processing and back-grinding of the wafer that includes the substrate 110. The p-epi layer 116 is formed across an upper surface 110US of the substrate 110. As the epitaxial name suggests, the p-epi layer 116 is grown as a crystalline layer on a crystalline substrate (here, the substrate 110), as may be achieved using chemical vapor deposition (CVD) or other processes, and with a relatively low doping level. The epi growth may be preceded by a cleaning and/or other surface treatment step, and followed by a thermal cycle, such as an annealing operation at a desired temperature and duration. The epi layer 116 may have a thickness TH1 (in the y-dimension) in a range from 1 to 5 μm.

After the epi layer 116 is formed, its upper surface is patterned and etched to form a downward trench that is filled with an insulator, for example silicon dioxide (SiO₂), to provide the deep trench isolation region 124. The deep trench isolation region 124 extends in part in the y-dimension through the p-epi layer 116, the upper surface 110US, and a portion of the substrate 110. Further, the deep trench isolation region 124 extends in the x-and z-dimensions to provide a partial or full isolating and surrounding perimeter, for example as shown in FIG. 1A as the x/y plane area within the boundary shown there by the deep trench isolation region 124. In FIG. 2, this area is generally indicated as an internal area 200, where capacitive and diode attributes are later realized.

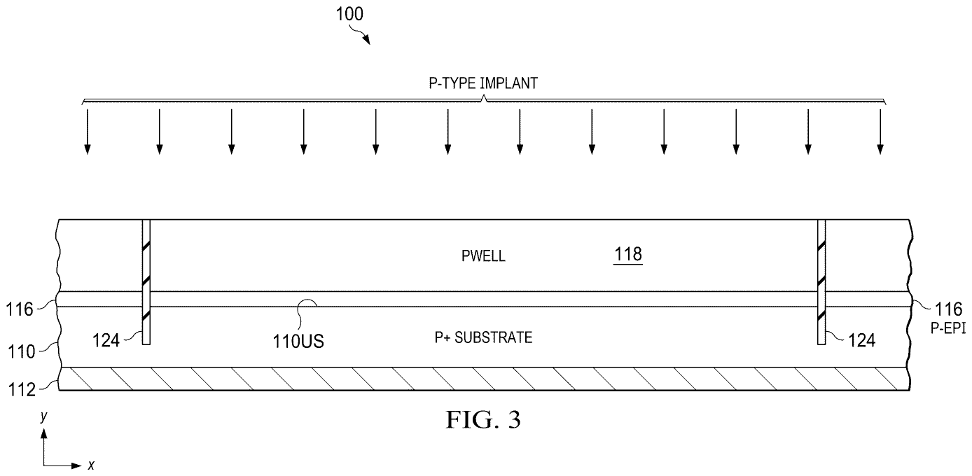

FIG. 3 illustrates a cross-sectional view of the IC 100 after additional processing following FIG. 2. In FIG. 3, a p-type dopant implant is directed toward the wafer frontside, that is, to the exposed surface of the FIG. 2 epi layer 116 (with or without a resist implant mask) and to implant p-type dopants, such as boron, to a desirable depth in the epi layer 116. The p-type dopants form the FIG. 3 Pwell layer 118, which is a distribution of p-type material caused by the illustrated implant. The depth and distribution of the implanted p-type dopants, as well as the dopant concentration from that depth upward, may be controlled to some extent by processing parameters, for example including the implant energy or number of implant steps. Also, a thermal cycle (annealing) may be used to repair damage caused by the ion implantation, to activate dopants, and for diffusion control.

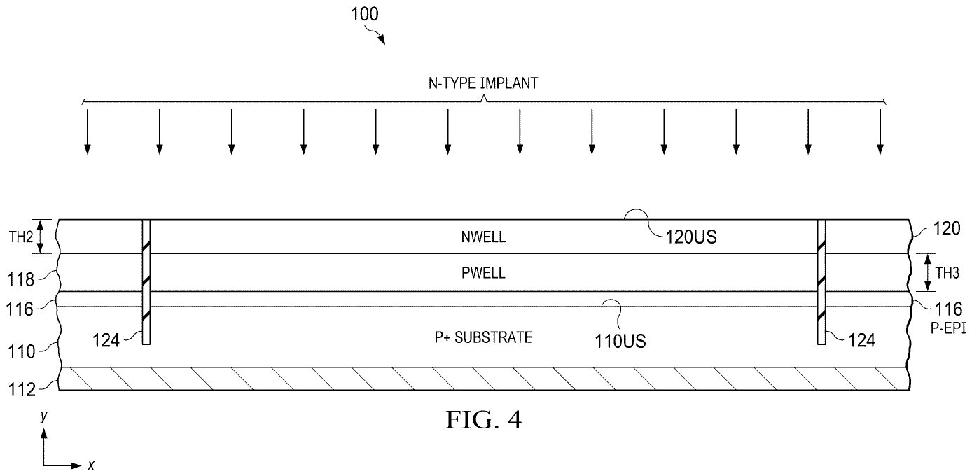

FIG. 4 illustrates a cross-sectional view of the IC 100 after additional processing following FIG. 3. In FIG. 4, an n-type dopant implant is directed toward the wafer frontside, that is, toward the FIG. 2 epi layer 116 which also from FIG. 3 includes the Pwell layer 118. The implant (with or without a resist implant mask) provides n-type dopants, such as arsenic, phosphorous, or antimony, to a desirable depth in what was previously the epi layer 116, and which may have additional p-type implants from the FIG. 3 implant, and the FIG. 4 n-type implant counterdopes the FIG. 3 p-type implant. Particularly, the FIG. 4 n-type implant achieves a higher concentration of n-type dopants near an upper surface 120US of what FIG. 4 illustrates as the resulting Nwell layer 120, which is an n-type region caused by the illustrated n-type implant. Accordingly, the depth and distribution of the implanted n-type dopants is such that the desired primary concentration of the n-type dopants is near the top of the y-dimension structure shown in FIG. 4. This dopant concentration also may be controlled to some extent by processing parameters, for example including the implant energy or number of implant steps, as well as a thermal cycle. Moreover, when the FIG. 4 implant/thermal cycle is complete, the average Nwell layer 120 dopant concentration may be in a range from 1 e17/cm³ to 9 e19/cm³, and a general thickness TH2 from the upper surface 120US from 0.5 μm to 2 μm.

Relatedly, also when the FIG. 4 implant/thermal cycle is complete and having followed the FIG. 3 p-type implant thermal cycle, the average Pwell layer 118 dopant concentration may be in a range from 1 E15/cm³ to 1 E17/cm³, and a general thickness TH3, between the Nwell layer 120 and the p-epi layer 116, from 0.5 μm to 4 μm. Note that since the Nwell layer 120 provides, in part, the resistive region 108, then its width/length ratio may be desirably adjusted so as to adjust the resistance of the resistive region 108, thereby impacting the overall impedance and response characteristic of the EMI filter 102. Lastly, while an n-type implant is shown to form an n-type region (the Nwell layer 120), in an alternative configuration, an epitaxially-formed (grown) n-type layer may be formed and serve to provide the n-type region for the PN junction further detailed below.

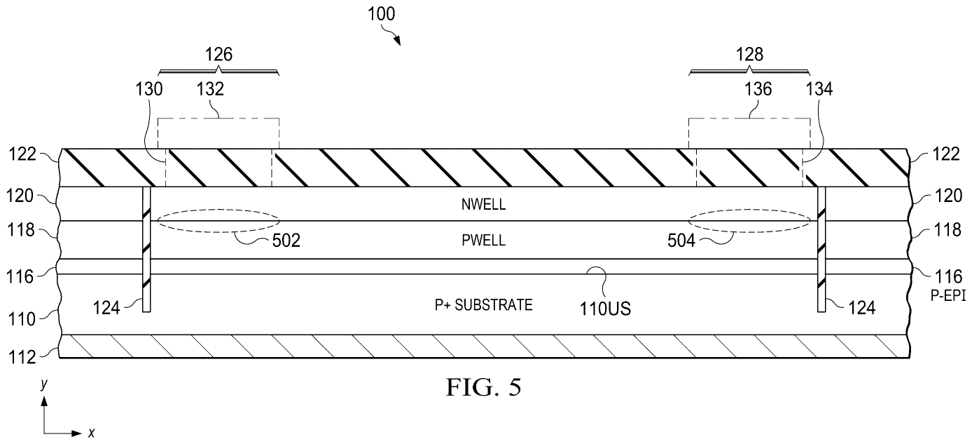

FIG. 5 illustrates a cross-sectional view of the IC 100 after additional processing following FIG. 4. In FIG. 5, the ILO layer 122 is formed above the Nwell layer 120. The ILO layer 122 may be formed, for example, with a CVD process, such as plasma-enhanced CVD (PECVD) or thermal CVD. After the insulating material forming the ILO layer 122 is deposited, it is planarized, for example using a chemical mechanical planarization (CMP) apparatus and methodology, thereby providing an upper planar surface for supporting any subsequently-formed structure. Indeed, additional processing after FIG. 5 provides the structure of FIG. 1B. Further in this regard, FIG. 5 also shows, in dashed outline, the locations and structure where the FIG. 1B first and second electrical terminals 126 and 128 are to be formed, either through or atop the ILO layer 122. Also while not shown, the terminals 126 and 128 may be connected to IC packaging PINs, for example via a wire bond, so that the filter can be accessed by the user.

The preceding descriptions of FIGS. 1-5 provide for two y-dimension (or “vertical”) diodes 104 and 106, with a resistive region 108 between the respective cathode of each of those diodes. From an implementation standpoint, the first diode 104 includes a first PN junction interface area 502, between the Pwell layer 118 and the Nwell layer 120, as generally aligned in the y-dimension beneath the first electrical terminal 126. Similarly, the second diode 106 includes a second PN junction interface area 504, between the Pwell layer 118 and the Nwell layer 120, as generally aligned in the y-dimension beneath the second electrical terminal 128. Each of the first and second PN junction interface areas 502 and 504 provides a junction that can reverse breakdown in a protection aspect as part of the Zener function of the first and second diodes 104 and 106. Also, each of the first and second PN junction areas 502 and 504 provides a depletion region that can store charge, effectively creating a respective inherent (or parasitic) capacitive structure in parallel with the respective one of the first and second diodes 104 and 106, as represented in FIG. 1C as the first and second capacitors 140 and 142. Further, the x-dimension outer boundary of each of the first and second diodes 104 and 106 may be considered as defined by the location of the deep trench isolation region 124.

Also, the resistive region 108 is along a resistive path provided by, or within, the portion of the Nwell layer 120 and mostly for that portion between the first and second PN junction interface areas 502 and 504. Also, note there is an absence of metal above that portion of the resistive path, as indicated in FIG. 1B as a non-metalized surface 120_NM. Also regarding this length portion of the Nwell layer 120 non-metalized surface 120_NM, it may be further characterized by a distance D1 (see FIGS. 1A and 5) in the x-dimension along the portion of the Nwell layer 120 that has the width of W1 in in the z-dimension, as shown in FIG. 1A. In other words, most of the resistance of the resistive region 108 is realized along D1, as resistance of the portions of the Nwell layer 120 immediately under and surrounding the first and second electrical terminals 126 and 128 is significantly lower and can be ignored as part of the total resistance. In different example implementations, ranges for these dimensions may include 50 μm≤D1≤200 μm and 50 μm≤W1≤200 μm.

FIGS. 6A and 6B illustrate a plan and cross-sectional view of an IC, respectively, including a first alternative IC with EMI filter 600 formed in connection with the IC semiconductor wafer. Various of the EMI filter 600 structures are the same or comparable to counterparts in the IC 100 of earlier figures, so certain above-described details are not reiterated. Generally, the EMI filter 600 includes the first and second electrical terminals 126 and 128 and an N-well located resistive region 108 between them. Accordingly, a first vertical diode 104 is located in the vertical (y-dimension) below the first electrical terminal 126. Also, a second vertical diode 106 is located in the vertical (y-dimension) below the second electrical terminal 128. Further, the deep trench isolation region 124 surrounds the combination of the first vertical diode 104, the second vertical diode 106, and the resistive region 108 between them.

Also, however, the EMI filter 600 includes a third vertical diode 602 and a fourth vertical diode 604 (the fourth vertical diode 604 is not shown in FIG. 6B, due to the location of the cross-sectional line as indicated in FIG. 6A). The third vertical diode 602 includes, in the y-dimension, a first deep isolation perimeter 606, formed at the same time and using the same process as the deep trench isolation region 124, within which is located vertically a respective portion 120_1 of the Nwell layer 120, and below which is a respective portion 118_1 of the Pwell layer 118, with the two layer portions thereby providing the PN junction interface for the third vertical diode 602. Similarly, the fourth vertical diode 604 includes, a second deep isolation perimeter 608, formed at the same time and using the same process as the deep trench isolation region 124, within which is located vertically a respective portion 120_2 of the Nwell layer 120, and below which is a respective portion of the Pwell layer 118, with the two layer portions thereby providing the PN junction interface for the fourth vertical diode 604.

The four diodes 104, 106, 602, and 604, of the EMI filter 600, are electrically connected to one another by metal structures in an x/z plane atop the ILO layer 122, as shown generally in FIG. 6A. Specifically, recall in an earlier example as shown in FIG. 1A, the first electrical terminal 126 is vertically above the first vertical diode 104 and the second electrical terminal 128 is vertically above the second vertical diode 106. This same structural relationship exists in FIGS. 6A and 6B, while in addition each of the first and second terminal 126 and 128 includes a respective extension beyond the perimeter of the deep trench isolation region 124. Specifically, the first terminal 126 includes an extension 126E extending away from the area of the first diode 104 and reaching to and above the area of the third diode 602. Similarly, the second terminal 128 includes an extension 128E extending away from the area of the second diode 106 and reaching to and above the area of the fourth diode 604. Accordingly, the anode/cathode paths of the first and third diodes 102 and 602 are in parallel, and the anode/cathode paths of the second and fourth diodes 104 and 604 are in parallel, with the resistive region 108 connected between those parallel/paired diode paths.

FIG. 7 illustrates a plan view of an IC, including a second alternative IC with EMI filter 700 formed in connection with the IC semiconductor wafer. Various of the EMI filter 700 structures are the same or comparable to counterparts in the IC 100 of earlier figures, so certain above-described details are not reiterated. Generally, the EMI filter 700 includes the first and second electrical terminals 126 and 128 and an N-well located resistive region 108 between them. Each of the first and second semiconductor vertical diodes has a PN interface area that is fully surrounded, in the y-dimension, by a respective deep trench isolation region 124_1 and 124_2. From the FIG. 7 perspective, in the x/z plane and within each of the deep trench isolation regions 124_1 and 124_2 is visible a respective portion 120_1 and 120_2 of the Nwell layer 120 (below which is a corresponding and respective portion of the Pwell layer 118, which is not visible in FIG. 7). Accordingly, a first semiconductor vertical diode 104 is located in the vertical (y-dimension) below the first electrical terminal 126, and a second semiconductor vertical diode 106 is located in the vertical (y-dimension) below the second electrical terminal 128.

In the second alternative EMI filter 700, the N-well located resistive region 108 includes plural parallel resistive elements, shown by example to include three such resistive elements 108_1, 108_2, and 108_3. Each of the parallel resistive elements 108_1, 108_2, and 108_3 represents a respective portion of the Nwell layer 120 (e.g., FIG. 1B), having an upper surface along which there is no metallization. Further, each of the parallel resistive elements 108_1, 108_2, and 108_3 is surrounded, in the y-dimension, but a respective isolating region 124_3, 124_4, and 124_5. In an example, all of the isolating regions 124_1, 124_2, 124_3, 124_4, and 124_5 are concurrently formed, using a process comparable to that described above in connection with the deep trench isolation region 124 of FIG. 2 (and other Figures).

Also in the second alternative EMI filter 700, each of the resistive elements 108_1, 108_2, and 108_3 is electrically connected to another one of the resistive elements. For example, a first metal coupler 702, as may be formed at the same time and in the same plane as the first and second terminals 126 and 128, electrically connects a first distal end the resistive element 108_1 to a first distal end of the resistive element 108_2. As another example, a first metal coupler 704, as also may be formed at the same time and in the same plane as the first and second terminals 126 and 128, electrically connects a second distal end the resistive element 108_2 to a first distal end of the resistive element 108_3. Accordingly, the plural resistive elements are connected, approximately in series, to form the resistive region 108 (and to cumulatively establish its resistance).

Also in the second alternative EMI filter 700, the resistive region 108, formed by the plural resistive elements 108_1, 108_2, and 108_3, is connected between the first and second terminals 126 and 128. More specifically, the first terminal 126 includes an extension 126E extending away from the area of the first diode 104 and reaching to and above the second distal end of the resistive element 108_1. Similarly, the second terminal 128 includes an extension 128E extending away from the area of the second diode 106 and reaching to and above the second distal end of the resistive element 108_3.

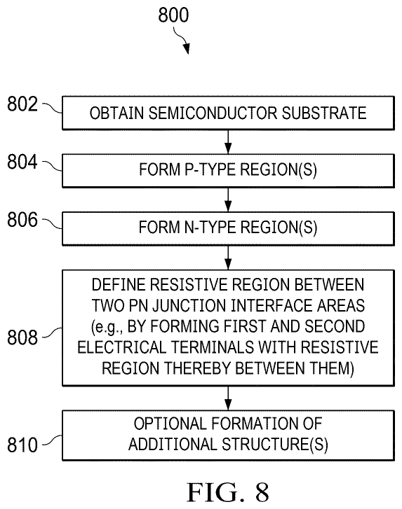

FIG. 8 is a flow diagram of an example method 800 summarizing various of the above-described steps for manufacturing the IC 100, for example as depicted in FIGS. 1A-5 (or similarly the IC filters of FIGS. 6A and 6B, or FIG. 7). The method 800 begins with a block 802, in which the FIG. 1B semiconductor substrate 110 is obtained. The semiconductor substrate 110 at this stage may be a bare wafer or may have the backside metal layer 112 and/or one or more semiconductor features already formed on it.

Next, in a block 804, one or more p-type regions are formed relative to the semiconductor substrate 110. For example, the block 804 may be represented in FIGS. 2 and 3 with the formation of the epi layer 116 and the Pwell layer 118 in a portion of the epi layer 116.

Next, in a block 806, one or more n-type regions are formed relative to the semiconductor substrate 110 and the p-type region(s). For example, the block 806 may be represented in FIG. 4 with the formation of the Nwell layer 120. Accordingly, the combination of blocks 804 and 806 provides a continuous PN interface, along which interface areas may be identified for creating respective vertical diodes across those areas, such as in the examples of the first and second PN junction interface areas 502 and 504.

Next, in a block 808, a resistive region is defined extending at least between the first and second PN junction interface areas 502 and 504, for example by forming first and second electrical terminals at an approximate distance slightly greater than D1 apart along the resistive region. For example, the block 808 may be represented in FIGS. 1A and 5 with the formation of the first electrical terminal 126 and a second electrical terminal 128. After the block 808, as shown generally in a block 810, additional structures may be formed, for example including one or more additional insulating and/or encapsulating structures.

From the above, one skilled in the art may appreciate that examples are provided for semiconductor fabrication, for example with respect to an IC that includes an EMI filter. The EMI filter may be achieved with at least two vertical diodes and a resistance between the respective diode cathodes, and without metallization along the resistance. Avoidance of metallization along the resistance may provide one or more benefits, for example reducing a processing step or steps and costs and/or masking associated with such a step(s). Such examples may provide various other benefits, some of which are described above and including still others. Further, various examples are provided, with a first example with a single resistive region between two vertical diodes, a second example with paired parallel-connected diodes and a resistive region between each pair, and a third example with plural resistive regions between two vertical diodes. Indeed, each of the second and third example may, for example, fit the same overall outer area boundary (in the x/z plane) as the first example, while providing additional impedance tuning and/or other benefits.

Additional modifications are possible in the described examples, and other examples are possible, within the scope of the following claims.

What is claimed is:

1. An integrated circuit (IC), comprising:
a first semiconductor diode, including a first portion of a first layer having a first conductivity type, a first portion of a second layer having a second conductivity type, and a first metal portion coupled to the first portion of the first layer, the first conductivity type opposite the second conductivity type and a first interface region aligned with the first metal portion and existing along an interface between the first and second layers;
a second semiconductor diode, including a second portion of the first layer, a second portion of the second layer, a second metal portion coupled to the second portion of the first layer, and a second interface region aligned with the second metal portion and existing along the interface between the first and second layers; and
a resistive region within the first layer and between the first interface region and the second interface region.

2. The IC of claim 1 wherein each of the first and second semiconductor diodes includes an anode and a cathode, and further including a differential input coupled across the anode/cathode of the first semiconductor diode, a differential output coupled across the anode/cathode of the second semiconductor diode, a first terminal of the resistive region coupled to the cathode of the first semiconductor diode, and a second terminal of the resistive region coupled to the cathode of the second semiconductor diode.

3. The IC of claim 1, wherein the first layer includes an Nwell and the second layer includes a Pwell.

4. The IC of claim 3, wherein each of the Nwell and the Pwell is formed in an epitaxial layer.

5. The IC of claim 1 and further including an isolating region extending through at least the first and second layers and surrounding the first and second semiconductor diodes and the resistive region.

6. The IC of claim 1 and further including:
a third semiconductor diode, including a third portion of the first layer and a third portion of the second layer, wherein the first metal portion includes a first extension coupled to the third portion of the first layer and the third semiconductor diode includes a third interface region aligned with the first extension and existing along the interface between the first and second layers; and
a fourth semiconductor diode, including a fourth portion of the first layer and a fourth portion of the second layer, wherein the second metal portion includes a second extension coupled to the fourth portion of the first layer and the fourth semiconductor diode includes a fourth interface region aligned with the second extension and existing along the interface between the first and second layers.

7. The IC of claim 6 and further including:
a first isolating region extending through at least the first and second layers and surrounding the first and second semiconductor diodes and the resistive region;
a second isolating region extending through at least the first and second layers and surrounding the third semiconductor diode; and
a third isolating region extending through at least the first and second layers and surrounding the fourth semiconductor diode.

8. The IC of claim 1, further including:
a third semiconductor diode coupled in parallel with the first semiconductor diode; and
a fourth semiconductor diode coupled in parallel with the second semiconductor diode.

9. The IC of claim 8:
wherein each of the first, second, third, and fourth semiconductor diodes includes an anode and a cathode; and
wherein the resistive region includes a first terminal coupled to the cathode of the first and third semiconductor diodes and a second terminal coupled to the cathode of the second and fourth semiconductor diodes.

10. The IC of claim 8 and further including:
a first isolating region extending through at least the first and second layers and surrounding the first and second semiconductor diodes and the resistive region;
a second isolating region extending through at least the first and second layers and surrounding the third semiconductor diode; and
a third isolating region extending through at least the first and second layers and surrounding the fourth semiconductor diode.

11. The IC of claim 1, wherein the resistive region includes a plurality of parallel resistive portions, wherein each of the parallel resistive portions is surrounded by a respective isolating region.

12. The IC of claim 11 and further including a respective metal portion coupling each of the parallel resistive portions to at least one other of the of the parallel resistive portions.

13. The IC of claim 12 wherein each of the first metal portion and the second metal portion includes a respective coupling to a respective one of the parallel resistive portions.

14. An integrated circuit (IC), comprising:
a first semiconductor diode, including a first portion of a first layer having a first conductivity type, a first portion of a second layer having a second conductivity type, and a first metal portion coupled to the first portion of the first layer, the first conductivity type opposite the second conductivity type and a first depletion region having a first inherent capacitance aligned with the first metal portion and existing along an interface between the first and second layers;
a second semiconductor diode, including a second portion of the first layer, a second portion of the second layer, a second metal portion coupled to the second portion of the first layer, and a second depletion region having a second inherent capacitance aligned with the second metal portion and existing along the interface between the first and second layers; and
a resistive region in the first layer and between the first and second depletion regions.

15. The IC of claim 14 wherein each of the first and second semiconductor diodes includes an anode and a cathode, and further including a differential input coupled across the anode/cathode of the first semiconductor diode, a differential output coupled across the anode/cathode of the second semiconductor diode, a first terminal of the resistive region coupled to the cathode of the first semiconductor diode, and a second terminal of the resistive region coupled to the cathode of the second semiconductor diode.

16. The IC of claim 14 and further including an isolating region extending through at least the first and second layers and surrounding the first and second semiconductor diodes and the resistive region.

17. The IC of claim 14, further including:
a third semiconductor diode coupled in parallel with the first semiconductor diode; and
a fourth semiconductor diode coupled in parallel with the second semiconductor diode.

18. The IC of claim 17:
wherein each of the first, second, third, and fourth semiconductor diodes includes an anode and a cathode; and
wherein the resistive region includes a first terminal coupled to the cathode of the first and third semiconductor diodes and a second terminal coupled to the cathode of the second and fourth semiconductor diodes.

19. The IC of claim 17 and further including:
a first isolating region extending through at least the first and second layers and surrounding the first and second semiconductor diodes and the resistive region;
a second isolating region extending through at least the first and second layers and surrounding the third semiconductor diode; and
a third isolating region extending through at least the first and second layers and surrounding the fourth semiconductor diode.

20. The IC of claim 14, wherein the resistive region includes a plurality of parallel resistive portions, wherein each of the parallel resistive portions is surrounded by a respective isolating region.

21. A method of forming an integrated circuit (IC), comprising:
forming a first layer with a first set of regions of a first conductivity type;
forming a second layer with a second set of regions of a second conductivity type, wherein the second conductivity type is opposite to the first conductivity type and a first semiconductor diode is formed between a first region in the first set of regions and a first region in the second set of regions and a second semiconductor diode is formed between a second region in the first set of regions and a second region in the second set of regions; and
forming a first electrical contact in contact with a cathode of the first semiconductor diode and a second electrical contact in contact with a cathode of the second semiconductor diode, and such that a resistive region is defined within the first layer between the first electrical contact and the second electrical contact.
